(19) United States
(12) Patent Application Publication
(10) Pub. No.: US 2013/0286613 A1
(43) Pub. Date: Oct. 31, 2013

(54) LCD Module, LCD Device, and Backplane

(71) Applicant: Yinhung Chen, Shenzhen (CN)

(72) Inventor: Yinhung Chen, Shenzhen (CN)

(21) Appl. No.: 13/515,507

(22) PCT Filed: May 2, 2012
(86) PCT No.: PCT/CN12/74970

§ 371 Date: Jun. 13, 2012

(30) Foreign Application Priority Data
Apr. 26, 2012 (CN) 201210126220.X

(51) Int. Cl. H05K 1/00

(52) U.S. Cl. 361/761

(57) ABSTRACT

The invention provides an LCD module, an LCD device, and a backplane. The LCD module includes a backplane, and a circuit board arranged on a back of the backplane. The backplane is provided with a slot into which a circuit board is inserted, and the circuit board are arranged on the slot. In the invention, because the backplane of the LCD module is provided with the slot, the circuit board of the LCD module is fixed in the slot of the backplane by insertion. Thus, a screw is not used for fixing a plurality of fixed points of the circuit boards, thereby improving the assembly efficiency of the circuit board and the LCD modules.

### TECHNICAL FIELD

The invention relates to the field of liquid crystal displays (LCDs), and more particularly to an LCD module, an LCD device, and a backplane.

### BACKGROUND

The production efficiency of LCD devices is related to the cost thereof. With the development of LCD technology, the structure, material, etc. of LCD devices should be continuously improved, to improve the display effect and reduce the cost of the LCD devices.

FIG. 1 and FIG. 2 show diagrams of arrangement of a circuit board on a backplane of an LCD module. As shown in the Figures, the backplane 10 is provided with circuit boards including a signal circuit board (X board) 20, and a control circuit board (C board) 30 which is connected with the signal circuit board 20 by a flexible flat cable (FFC) 25 and a connector 21. The signal circuit board 20 is connected with the LCD module by a chip on film (COF) 40, and the signal circuit board 20 and the control circuit board 30 are locked on the backplane 10 by a screw 11. A plurality of screws 11 are used when one circuit board is locked on the backplane, thereby increasing the assembly time of the circuit boards, and affecting the assembly efficiency of the LCD devices.

### SUMMARY

In view of the above-described problems, the aim of the invention is to provide an LCD module, an LCD device, and a backplane with the advantages of convenient assembly and high assembly efficiency.

The aim of the invention is achieved by the following technical scheme.

An LCD module comprises a backplane and a circuit board arranged on a back of the backplane; the backplane is provided with a slot into which the circuit board is inserted, and the circuit board is arranged in the slot.

Preferably, the slot is of a metal structure, and a contact position of the circuit board and the slot is provided with a bare copper zone. The slot can be used for earthing, thereby saving the earthing process.

Preferably, the circuit board comprises a signal circuit board and a control circuit board connected with the signal circuit board. Corresponding circuit board is selected to be arranged on the back of the backplane as required, and is assembled by the slot, thereby improving the assembly efficiency of the circuit board.

Preferably, the signal circuit board is provided with a protrusion with a connecting finger, and the control circuit board is provided with a connector in the position corresponding to the connecting finger of the signal circuit board. The connecting finger of the protrusion is inserted into the connector. By respectively arranging the connecting finger and the connector on the signal circuit board and the control circuit board, the circuit boards are connected after being inserted into the guide slot, thereby improving the assembly efficiency of the circuit boards.

Preferably, both an upper side and a lower side of the protrusion are provided with the connecting fingers, and the signal circuit board is connected with the connector by the connecting fingers on both the upper side and the lower side of the protrusion. The pin number on the protrusion is increased, to favor the circuit design.

Preferably, the slot comprises a plurality of parallel guide slots which are arranged on both sides of the circuit board for insertion of the circuit board. The circuit board is inserted into a plurality of parallel guide slots, to facilitate the connection between the circuit boards.

Preferably, the slot further comprises a limit slot which is arranged at an end of the insertion direction of the guide slot for limiting the position of the circuit board. The limit slot is arranged at the end of the inserting direction of the guide slot, to improve the assembly accuracy.

Preferably, the slot and the backplane are of an integrated structure. Thus, the slot need not be arranged additionally, the production process is omitted, and the circuit board is earthed by directly using the backplane.

An LCD device comprises the LCD module mentioned above.

A backplane, the backplane is provided with a slot into which a circuit board is inserted.

In the invention, because the backplane of the LCD module is provided with the slot, the circuit board of the LCD module is fixed in the slot of the backplane by insertion. Thus, a screw is not used for fixing a plurality of fixed points of the circuit board, and the assembly efficiency of the circuit boards is improved, thereby improving the assembly efficiency of the LCD module.

### BRIEF DESCRIPTION OF FIGURES

FIG. 1 is a simplified diagram of an arrangement of a circuit board of a conventional LCD module;

FIG. 2 is a left view of FIG. 1;

FIG. 3 is a simplified diagram of an arrangement of a circuit board of an LCD module of an example of the invention;

FIG. 4 is a left view of FIG. 3;

FIG. 5 is a simplified diagram of a fixing mode of a signal circuit board of the invention;

FIG. 6 is a left view of FIG. 5;

FIG. 7 is an A-A view shown in FIG. 5;

FIG. 8 is a simplified diagram of a connecting between a control circuit board and a signal circuit board of an example of the invention;

FIG. 9 is a B-B view shown in FIG. 8; and

FIG. 10 is a simplified diagram of a structure of a control circuit board of an example of the invention.

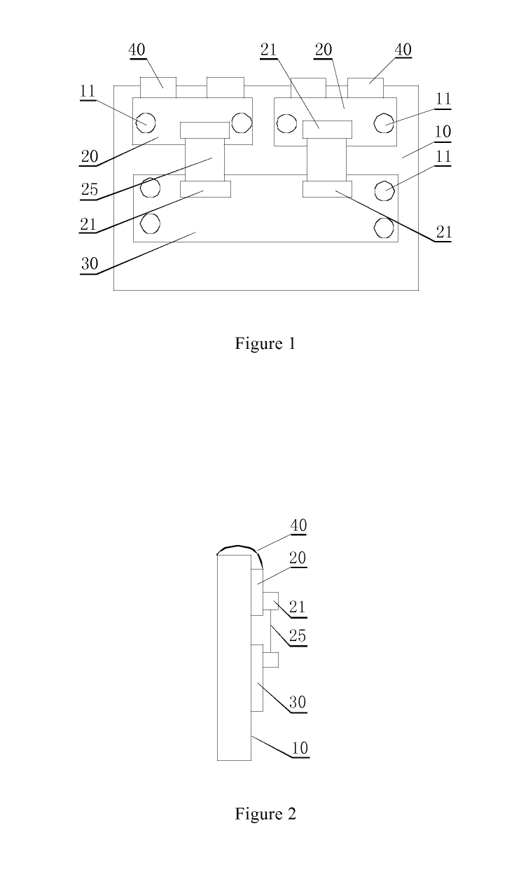

Legends: 10. backplane; 11. screw; 12. guide slot; 13. limit slot; 20. signal circuit board; 21. connector; 25. FFC; 27. bare copper; 30. control circuit board; 31. protrusion; 37. connecting figure; 40. chip on film.

### DETAILED DESCRIPTION

The invention will further be described in detail in accordance with the figures and the preferable examples.

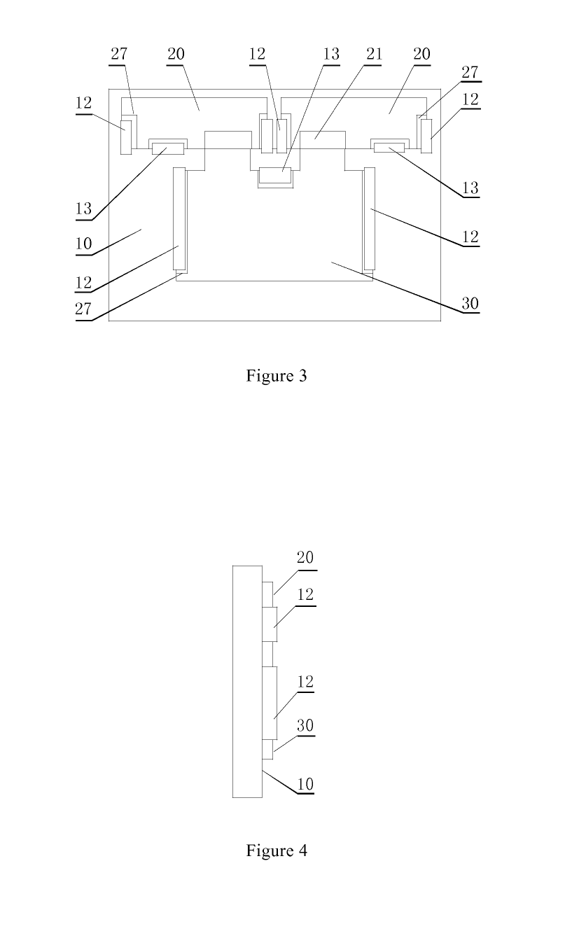

FIG. 3 and FIG. 4 show diagrams of an assembly of a circuit board of an LCD module of the invention. As shown in the Figures, a backplane 10 of an LCD module is provided with a guide slot 12 into which the circuit board is inserted and a limit slot 13. The circuit board comprises a signal circuit board 20 and a control circuit board 30. Because the backplane 10 of the LCD module is provided with the slots, the circuit board of the LCD module is fixed in the slots of the backplane 10 by insertion. Thus, a screw is not used for fixing a plurality of fixed points of the circuit board, thereby improving the assemble efficiency of the circuit board, and further improving the assembly efficiency of LCD module.

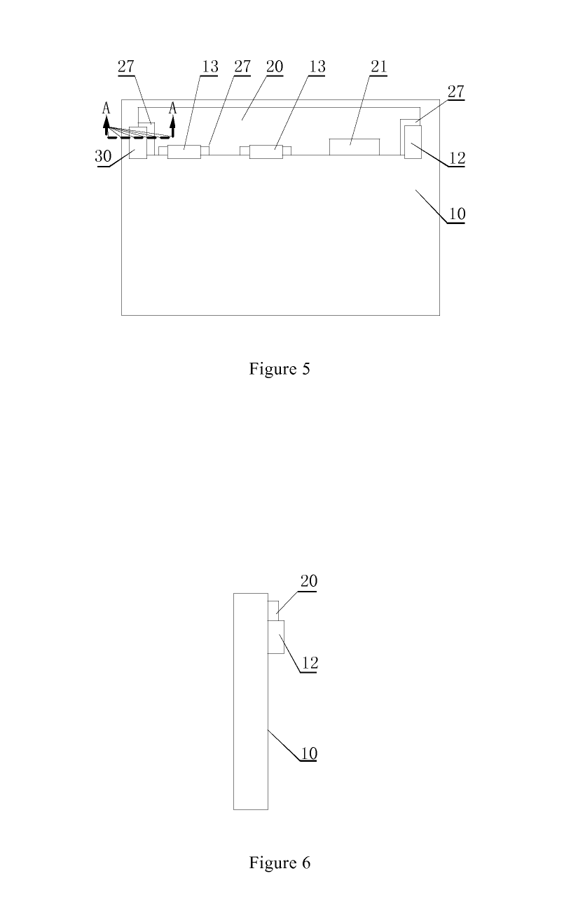

FIGS. 5-7 show a fixing mode of the signal circuit board 20. As shown in the Figures, the backplane 10 of the LCD module is provided the guide slot. The guide slot is of a rectangle groove structure, and an opening direction thereof is in parallel with the surface of the backplane 10. Thus, a printed circuit board (PCB) is well locked on the backplane 10. When being assembled, the signal circuit board 20 is inserted into the slot from one end of the guide slot 12. The backplane 10 is further provided with the limit slot 13 which is positioned at the end of the inserting direction of the guide slot 12. Similar to the guide slot 12, the limit slot 13 is of a rectangle groove structure, and the opening direction thereof is in parallel with the surface of the backplane 10. The limit slot 13 is used for limiting the position of the signal circuit board 20 after being inserted. Optionally, the limit slot 13 can be of other limit structures such as lug boss, and the structure of the slot can make the PCB to be better locked on the backplane 10. Similarly, as shown in FIG. 3, the backplane 10 is also provided with the guide slot 12 into which the control circuit board 30 is inserted and the limit slot 13 for limiting the position of the control circuit board 30.

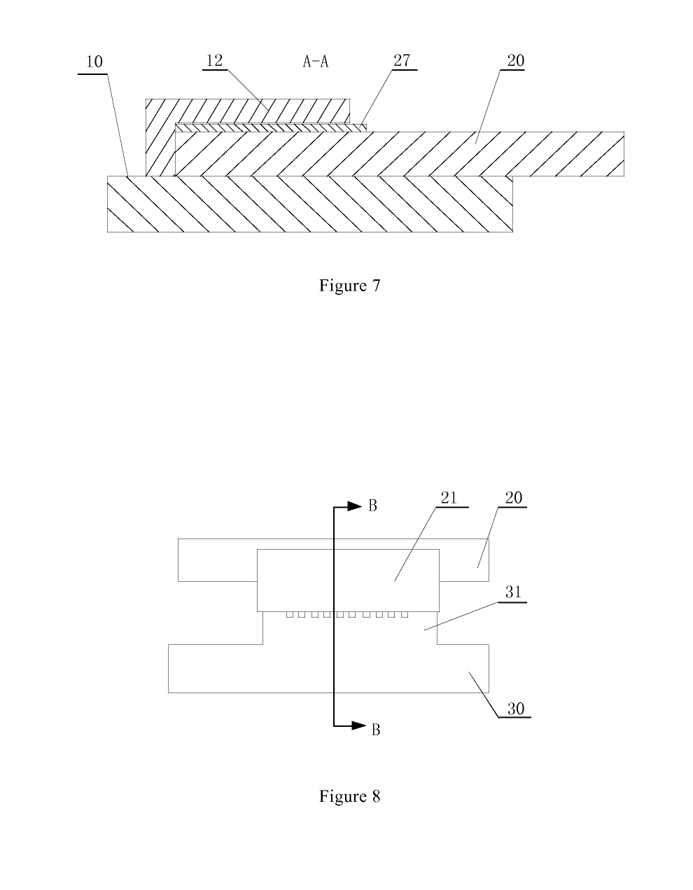

As shown in FIG. 7, the signal circuit board 20 is provided with a bare copper 27 zone, and the bare copper 27 is in contact with the metal slot. If the backplane is also of a metal structure, an earthing design is achieved by the contact between the slot and the backplane. If the backplane is of a non-conducting structure, the earthing design is achieved by additionally arranging a circuit to connect with the slot. Optionally, as shown in FIG. 3, a plurality of zones of the signal circuit board 20 and the control circuit board 30 which are in contact with the slot are respectively provided with the bare copper 27.

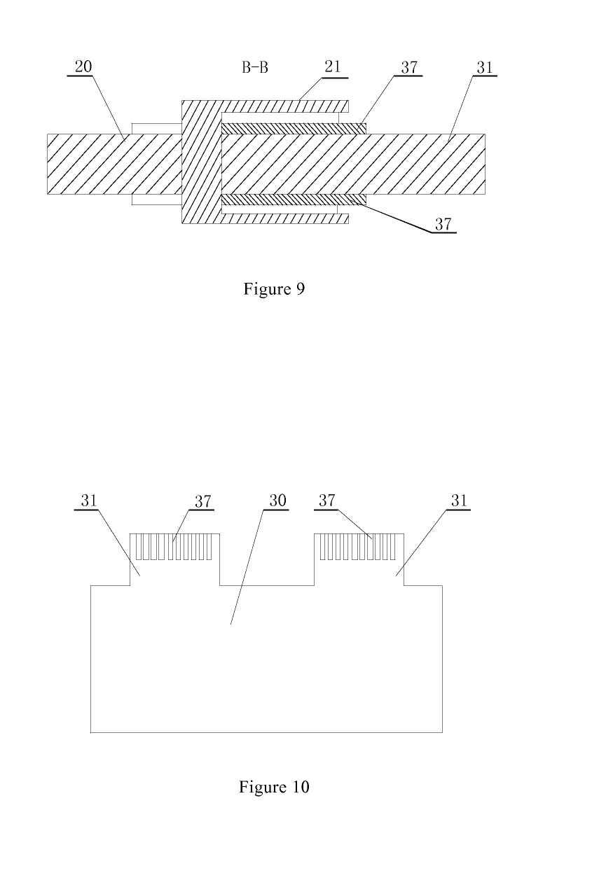

As shown in FIG. 8 and FIG. 9, the signal circuit board 20 is also connected with the control circuit board 30 by insertion. The control circuit board 30 is provided with a protrusion 31 to form a plug structure. As shown in FIG. 10, the protrusion 31 is provided with a connecting finger 37; correspondingly, the signal circuit board 20 is provided with a connector 21 in the position corresponding to the connecting finger 37. As shown in FIG. 3, all the guide slots 12 are arranged in parallel, thereby facilitating to control the butting between the control circuit board 30 and the signal circuit board 20. When being assembled, the signal circuit board 20 is positioned in the slot, the control circuit board 30 is inserted along the guide slot 12, the connecting finger 37 of the protrusion 31 is inserted in the connector 21 of the signal circuit board 20 which is positioned, and then the signal circuit board 20 is connected with the control circuit board 30. Thus, the step for arranging an FFC is omitted, the use of the FFC is omitted, and the number of the connector is reduced by half. Optionally, the protrusion can be correspondingly arranged on the signal circuit board and the protrusion can be provided with the connecting finger; correspondingly, the connector can be arranged on the control circuit board in the position corresponding to the connecting finger.

To increase the pin number of the protrusion, as shown in FIG. 9, both sides of the protrusion 31 are respectively provided with the connecting fingers 37, and the signal circuit board is connected with the connector of the control circuit board by the connecting fingers 37 arranged on the upper side and lower side of the protrusion, thereby favoring the circuit arrangement.

In the example of the invention, the slot is integrated with the backplane. For example, the slot can be directly formed on the backplane by punching; optionally, the slot can be arranged by other modes. However, other modes for arranging the slot is complicated.

Optionally, the example of the invention only describes the modes that the signal circuit board and the control circuit board are provided with the slot and are assembled by the slot. Other circuit boards can also be arranged by the slot to improve the arrangement efficiency.

The invention is described in detail in accordance with the above contents with the specific preferred examples. However, this invention is not limited to the specific examples. For the ordinary technical personnel of the technical field of the invention, on the premise of keeping the conception of the invention, the technical personnel can also make simple deductions or replacements, and all of which should be considered to belong to the protection scope of the invention.

We claim:

1. An LCD module, comprising: a backplane and a circuit board arranged on a back of said backplane; wherein said backplane is provided with a slot into which said circuit board is inserted, and said circuit board is arranged in said slot by insertion.

2. The LCD module of claim 1, wherein said slot is of a metal structure, and a contact position of said circuit board and said slot is provided with a bare copper zone.

3. The LCD module of claim 1, wherein said circuit board comprises a signal circuit board, and a control circuit board connected with said signal circuit board.

4. The LCD module of claim 3, wherein said signal circuit board is provided with a protrusion with a connecting finger, and said control circuit board is provided with a connector in the position corresponding to the connecting finger of said signal circuit board; and the connecting finger of said protrusion is inserted in said connector.

5. The LCD module of claim 4, wherein both an upper side and a lower side of said protrusion are respectively provided with said connecting fingers, and said signal circuit board is connected with said connector by said connecting fingers on both the upper side and the lower side of said protrusion.

6. The LCD module of claim 1, wherein said slot comprises a plurality of parallel guide slots which are arranged on both sides of said circuit board for insertion of said circuit board.

7. The LCD module of claim 6, wherein said slot further comprises a limit slot which is arranged at an end of the inserting direction of said guide slot for limiting the position of said circuit board.

8. The LCD module of claim 1, wherein said slot and said backplane are of an integrated structure.

9. An LCD device, comprising: a backplane, and a circuit board arranged on a back of said backplane; wherein said backplane is provided with a slot into which said circuit board is inserted, and said circuit board is arranged in said slot by insertion.

10. The LCD device of claim 9, wherein said slot is of a metal structure, and a contact position of said circuit board and said slot is provided with a bare copper zone.

11. The LCD device of claim 9, wherein said circuit board comprises a signal circuit board, and a control circuit board connected with said signal circuit board.

12. The LCD device of claim 11, wherein said signal circuit board is provided with a protrusion with a connecting finger, and said control circuit board is provided with a connector in the position corresponding to said connecting finger of said signal circuit board; and said connecting finger of said protrusion is inserted in said connector.

13. The LCD device of claim 12, wherein both an upper side and a lower side of said protrusion are respectively provided with said connecting fingers, and said signal circuit board is connected with said connector by said connecting fingers on both the upper side and the lower side of said protrusion.

14. The LCD device of claim 9, wherein said slot comprises a plurality of parallel guide slots which are arranged on both sides of said circuit board for insertion of said circuit board.

15. The LCD device of claim 14, wherein said slot further comprises a limit slot which is arranged at an end of said guide slot for limiting the position of said circuit board.

16. The LCD device of claim 9, wherein said slot and said backplane are of an integrated structure.

17. A backplane, wherein said backplane is provided with a slot into which a circuit board is inserted.
